(19) United States
(12) Patent Application Publication
(10) Pub. No.: US 2022/0199379 A1
(43) Pub. Date: Jun. 23, 2022

(54) HIGH TEMPERATURE HEATING OF A SUBSTRATE IN A PROCESSING CHAMBER

(71) Applicant: LAM RESEARCH CORPORATION, Fremont, CA (US)

(72) Inventors: James F. LEE, Casper, WY (US); Matthew MUDROW, Tigard, OR (US); Rand Arthur CONNER, Beaverton, OR (US); Fayaz A. SHAIKH, Lake Oswego, OR (US); Damien Martin SLEVIN, Salem, OR (US)

(21) Appl. No.: 17/605,264

(22) PCT Filed: Apr. 21, 2020
(86) PCT No.: PCT/US2020/029053

§ 371 Date: Oct. 21, 2021

Related U.S. Application Data
(60) Provisional application No. 62/839,154, filed on Apr. 26, 2019.

(51) Int. Cl. H01J 37/32

(52) U.S. Cl. CPC H01J 37/32724; H01J 37/32495; H01J 37/3244; H01J 37/32082

(57) ABSTRACT

A processing chamber includes: a lower portion; an upper portion that covers the lower portion; a pedestal that is located within the lower portion, to vertically support a substrate above a top surface of the pedestal to distribute a precursor between the top surface and a first surface of the substrate, the pedestal configured to be electrically connected to one of a ground potential and a radio frequency potential; a grid that is coupled to the upper portion and that is configured to be electrically connected to the other one of the ground potential and the radio frequency potential; a window that covers an opening in the upper portion; and an infrared light source configured to transmit infrared light through the window and the grid to a second surface of the substrate. The second surface of the substrate is opposite the first surface of the substrate.

### CROSS-REFERENCE TO RELATED APPLICATIONS

This application claims the benefit of U.S. Provisional Application No. 62/839,154, filed on Apr. 26, 2019. The entire disclosure of the application referenced above is incorporated herein by reference.

### FIELD

The present disclosure relates to substrate processing systems and more particularly to systems to heat substrates in plasma processing chambers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to process substrates, such as semiconductor wafers. Example processes that may be performed on a substrate include, but are not limited to, deposition, etching, cleaning, and other types of processes. A substrate may be arranged on a substrate support, such as a pedestal or an electrostatic chuck (ESC), in a processing chamber. During processing, gas mixtures may be introduced into the processing chamber and plasma may be used to initiate chemical reactions.

A temperature of a substrate (e.g., a semiconductor wafer) in a processing chamber can be controlled. Heaters can be arranged in the substrate support assembly, and the power supplied to the heaters can be controlled to control the temperature of a substrate on the substrate support. Coolant can be circulated through one or more coolant channels in the substrate support using valves to heat and/or cool the substrate and the substrate support.

### SUMMARY

In a feature, a processing chamber includes: a lower portion; an upper portion that covers the lower portion; a pedestal that is located within the lower portion, to vertically support a substrate above a top surface of the pedestal to distribute a precursor between the top surface and a first surface of the substrate, the pedestal configured to be electrically connected to one of a ground potential and a radio frequency potential; a grid that is coupled to the upper portion and that is configured to be electrically connected to the other one of the ground potential and the radio frequency potential; a window that covers an opening in the upper portion; and an infrared light source configured to transmit infrared light through the window and the grid to a second surface of the substrate. The second surface of the substrate is opposite the first surface of the substrate.

In further features, the grid has an open area of approximately 88 percent.

In further features, the grid has an open area of at least 80 percent.

In further features, the infrared light source is configured to heat the substrate to at least 500 degrees Celsius.

In further features, the grid includes a coating that is resistant to fluorine etching.

In further features, an exterior of the grid is coated with alumina.

In further features, an exterior of the grid is coated with yytria.

In further features, the processing chamber further includes a radio frequency generator circuit configured to apply the ground potential and the radio frequency potential to the grid and the pedestal and to strike plasma with the precursor.

In further features, the processing chamber further includes a vacuum source configured to create a vacuum within the processing chamber.

In further features, the processing chamber further includes a second window that is secured to the upper portion, where the infrared light source is configured to transmit the infrared light through the window, the grid, and the second window to the second surface of the substrate.

In further features, the second window is located between the grid and the substrate.

In further features, the second window is located between the window and the grid.

In further features, the second window includes a plurality of holes.

In further features, the processing chamber further includes at least one purge gas conduit configured to inject a purge gas between the window and the second window, where the purge gas flows through the plurality of holes in the second window toward the second surface of the substrate.

In further features, a first thickness of the window is greater than a second thickness of the second window.

In further features, the grid is embedded within the second window.

In further features, the second window is selected from a group consisting of quartz and sapphire.

In further features, the window is selected from a group consisting of quartz and sapphire.

In further features, the infrared light source includes at least one infrared light bulb.

In further features, the infrared light source includes a plurality of blue light emitting diodes configured to generate infrared light.

In a feature, a processing chamber includes: a pedestal that is located within the processing chamber, the pedestal to: vertically support a substrate; and be electrically connected to one of a ground potential and a radio frequency potential; a grid to be electrically connected to the other one of the ground potential and the radio frequency potential; and an infrared light source to transmit infrared light through the window and the grid to a surface of the substrate.

In further features, the grid has an open area of approximately 88 percent.

In further features, the grid has an open area of at least 80 percent.

In further features, the infrared light source is to heat the substrate to at least 500 degrees Celsius.

In further features, the grid includes a coating that is resistant to fluorine etching.

In further features, an exterior of the grid is coated with alumina.

In further features, an exterior of the grid is coated with yytria.

In further features, a radio frequency generator circuit is to apply the ground potential and the radio frequency potential to the grid and the pedestal and to strike plasma with a precursor.

In further features, a vacuum source is to create a vacuum within the processing chamber.

In further features, the infrared light source is to transmit the infrared light through the window, the grid, and a second window to the surface of the substrate.

In further features, the second window is located between the grid and the substrate.

In further features, the second window is located between the window and the grid.

In further features, the second window includes a plurality of holes.

In further features, at least one purge gas conduit is to inject a purge gas between the window and the second window, where the purge gas flows through the plurality of holes in the second window toward the surface of the substrate.

In further features, a first thickness of the window is greater than a second thickness of the second window.

In further features, the grid is embedded within the second window.

In further features, the second window is selected from a group consisting of quartz and sapphire.

In further features, the window is selected from a group consisting of quartz and sapphire.

In further features, the infrared light source includes at least one infrared light bulb.

In further features, the infrared light source includes a plurality of blue light emitting diodes to generate infrared light.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including a processing chamber;

FIG. 2 is a cross-sectional diagram of an example implementation of the processing chamber;

FIG. 3 is a cross-sectional diagram of an example implementation of the processing chamber;

FIG. 4 is a cross-sectional diagram of an example implementation of the processing chamber;

FIG. 5 includes a top view of a portion of an example implementation of a grid of the processing chamber;

FIG. 6 includes a top view of a portion of an example implementation of a window of the processing chamber; and

FIG. 7 is a flowchart depicting an example method of depositing a film on a substrate.

In the drawings, reference numbers may be reused to identify similar and/or identical elements.

### DETAILED DESCRIPTION

A film may be deposited on a substrate within a processing chamber while the substrate sits upon a pedestal. For example, a substrate sits upon a showerhead pedestal within a processing chamber. The showerhead pedestal distributes a precursor to the substrate. An upper electrode (e.g., a grid) and a lower electrode (e.g., the showerhead pedestal) are used to strike radio frequency (RF) plasma between a top surface of the showerhead pedestal and a lower surface of the substrate to deposit a film on the lower surface of the substrate.

After the deposition of the film, the substrate may be heated to at least a first temperature (e.g., approximately 530 degrees Celsius) during performance of one or more other processes on the substrate. If the film is deposited onto the substrate at a temperature that is lower than the first temperature, the substrate may bend and/or bow during performance of the other processes due to internal stress of the film at higher temperatures.

According to the present disclosure, the processing chamber includes an infrared (IR) light source that transmits IR light onto a top surface of the substrate during deposition of the film on the lower surface of the substrate. The IR light from the IR light source warms the substrate to at least the first temperature. The deposition of the film onto the substrate while the substrate is heated to at least the first temperature may prevent or minimize a loss of stress properties of the film (e.g., from bowing and bending of the substrate) during performance of the other processes after the deposition of the film.

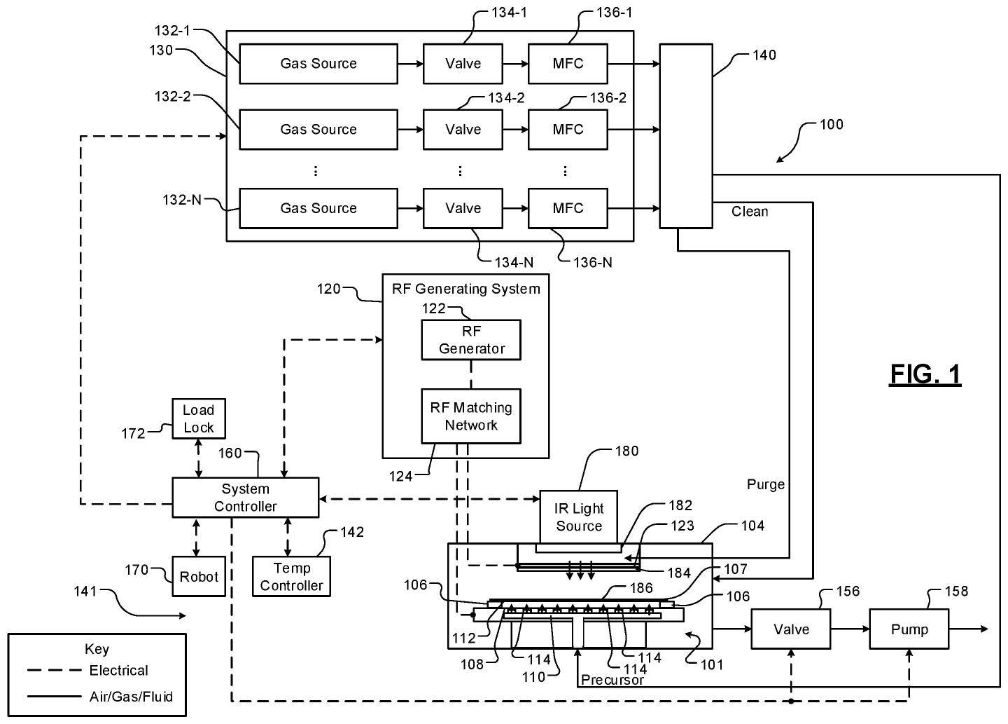

FIG. 1 includes a substrate processing system 100 including a showerhead pedestal 101 within a processing chamber 104. While the example of the showerhead pedestal 101 is provided, another type of pedestal may be used. Although FIG. 1 shows a capacitive coupled plasma (CCP) system, the present application may also be applicable to transformer coupled plasma (TCP) systems, electron cyclotron resonance (ECR) plasma systems, inductively coupled plasma (ICP) systems, and/or other systems and plasma sources that include a substrate support.

The showerhead pedestal 101 includes or is made of electrically conductive material, such as aluminum. One or more substrate supports 106 vertically support a substrate 107 above a top surface 108 of the showerhead pedestal 101. The substrate support(s) 106 may include, for example, an annular substrate support ring.

The showerhead pedestal 101 includes one or more internal plenums 110 that receive precursor gas and that distribute the precursor gas to a first (lower) surface 112 of the substrate 107 via holes 114 to deposit film on the first surface 112 of the substrate 107. The showerhead pedestal 101 is enclosed within the processing chamber 104. The processing chamber 104 also encloses other components and contains radio frequency (RF) plasma.

In various implementations, the showerhead pedestal 101 may include temperature control elements (TCEs). Additionally or alternatively, the showerhead pedestal 101 may include one or more coolant channels that flow coolant through the showerhead pedestal 101.

An RF generating system 120 includes one or more RF generators, such as RF generator 122, that generate and output RF voltages. For example, the RF generator 122 generates and outputs an RF voltage to a grid 123 (an RF grid), which serves as an upper electrode, and the showerhead pedestal 101, which serves as a lower electrode. One of the upper electrode and the lower electrode may be DC grounded, AC grounded, or at a floating potential. The other one of the upper electrode and the lower electrode may receive an RF potential. The RF generator 122 may be a high-power plasma RF generator producing, for example 6-10 kilo-watts (kW) of power or more. The RF generating system 120 may include one or more other RF generators (e.g., a bias RF power generator and/or other RF power generator) that generate and output one or more other RF voltages.

The output of the RF generator 122 is fed by an RF matching and distribution network 124 to the upper electrode and/or the lower electrode. Outputs of other RF generators may be fed by other RF matching and distribution networks to other electrodes.

A gas delivery system 130 includes one or more gas sources 132-1, 132-2, . . . , and 132-N (collectively gas sources 132), where N is an integer greater than zero. The gas sources 132 supply one or more precursors (Precursor) and gas mixtures thereof. The gas sources 132 may also supply one or more of etch gas, carrier gas, clean gas (Clean), and purge gas (Purge). Vaporized precursor may be used in various implementations.

The gas sources 132 may be connected by valves 134-1, 134-2, . . . , and 134-N (collectively valves 134) and mass flow controllers 136-1, 136-2, . . . , and 136-N (collectively mass flow controllers 136) to one or more manifolds, such as manifold 140. Gas output from the manifold(s) is fed to the processing chamber 104. For example only, an output of the manifold 140 may be fed to the showerhead pedestal 101. Different manifolds may be used to provide different types of gas to different locations within the processing chamber 104.

The substrate processing system 100 may include a cooling system that includes a temperature controller 142. Although shown separately from a system controller 160, the temperature controller 142 may be implemented as part of the system controller 160. The showerhead pedestal 101 may include a plurality of temperature controlled zones (e.g., 4 zones), where each of the temperature controlled zones includes one or more temperature sensors and one or more of the TCEs. Additionally or alternatively, the showerhead pedestal 101 may include one or more coolant channels. The temperature controller 142 may control operation of the TCEs of a zone based on the temperature(s) measured by the temperature sensor(s) of that zone. The temperature controller 142 may additionally or alternatively control coolant flow through the coolant channels based on one or more measured temperatures.

A valve 156 and a pump 158 create vacuum within the processing chamber 104. For example, the system controller 160 may control the pump 158 to adjust a pressure within the processing chamber 104 to approximately a first vacuum. The first vacuum may be, for example, approximately 1-2 torr, approximately 1.5 torr, or another suitable vacuum. As used herein, approximately may mean +/−10%. The valve 156 and the pump 158 or another valve and another pump may be used to evacuate gas from within the processing chamber 104.

A robot 170 may deliver substrates onto and remove substrates from the showerhead pedestal 101. For example, the robot 170 may transfer substrates between the showerhead pedestal 101 and a load lock 172. The system controller 160 may control operation of the robot 170. The system controller 160 may also control operation of the load lock 172.

An infrared (IR) light source 180 includes one or more devices that generate IR light. The IR light source 180 transmits IR light through a first window 182, the grid 123, and a second window 184 onto a second (top) surface 186 of the substrate 107. The system controller 160 controls the IR light source 180 to transmit IR light to the substrate 107 during deposition of the film onto the first surface 112 of the substrate 107. The IR light from the IR light source 180 heats the substrate 107 to a first temperature or greater than the first temperature. The first temperature may be, for example, approximately 500 degrees Celsius, approximately 530 degrees Celsius, or another suitable temperature that is greater than 500 degrees Celsius. While the example of the IR light source 180 is provided, another type of light source may be used in place of the IR light source 180. The present application is applicable to IR, non-IR, and other types of light sources and elements that output light that can heat the substrate 107.

After the deposition of the film, the substrate 107 may be heated to the first temperature or greater during performance of one or more other processes on the substrate 107. The deposition of the film onto the substrate 107 while the substrate 107 is heated by the IR light source 180 to at least the first temperature may prevent or minimize a loss of stress properties of the film during performance of the other processes. If the film was deposited onto the substrate 107 at lower temperatures, the substrate 107 may bend and/or bow during performance of the other processes due to internal stress of the film.

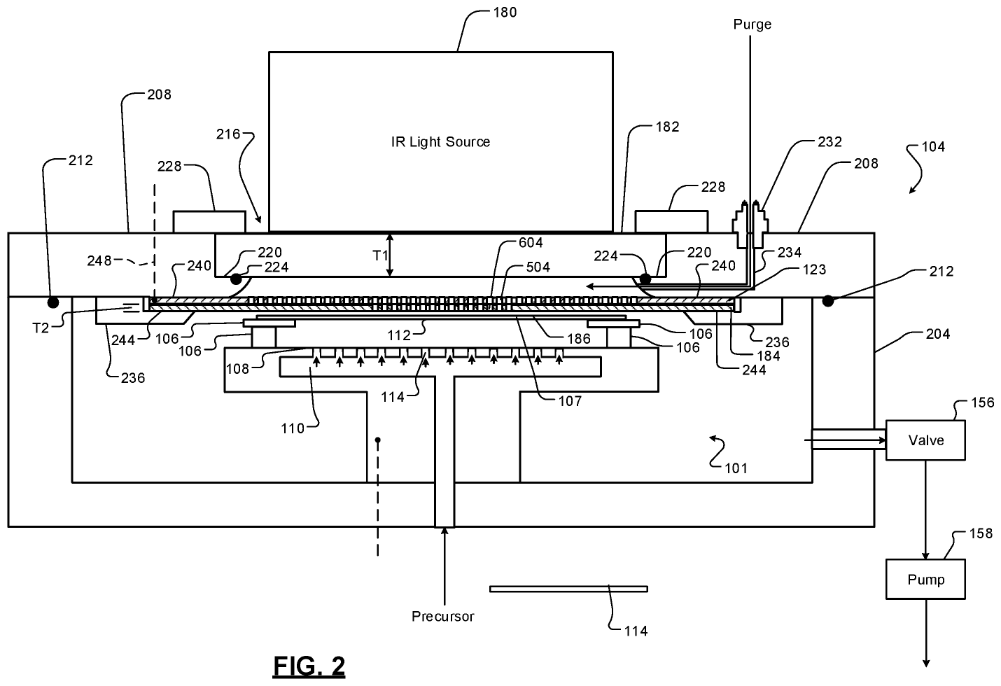

FIG. 2 is a cross-sectional diagram of an example implementation of the processing chamber 104. The processing chamber 104 includes a lower portion 204 and an upper portion 208. One or more sealing devices 212, such as one or more gaskets and/or one or more O-rings, may seal an interface between the lower portion 204 and the upper portion 208.

The upper portion 208 includes an opening 216. The first window 182 seals the opening 216. For example, the first window 182 may sit upon shoulders 220 formed or machined in the opening 216. One or more sealing devices 224, such as one or more gaskets and/or one or more O-rings, may seal an interface between the first window 182 and the shoulders 220.

One or more clamping devices 228 bias the first window 182 toward the upper portion 208 (e.g., the shoulders 220) and clamp the first window 182 to the upper portion 208. For example only, the one or more clamping devices 228 may include a clamp ring that includes threads that engage threads formed in the upper portion 208.

A purge gas fitting 232 receives purge gas. The purge gas flows from the purge gas fitting 232 through a conduit 234 in the upper portion 208 to between the first window 182 and the second window 184. The purge gas flows through the grid 123 and the second window 184 toward the substrate 107, as discussed further below.

One or more clamping devices 236 bias the second window 184 and the grid 123 toward a lower surface 240 of the upper portion 208. For example only, the one or more clamping devices 236 may include a clamp ring that includes threads that engage threads formed in the upper portion 208. The one or more clamping devices 236 may include shoulders 244 that vertically support the second window 184 and the grid 123.

The IR light source 180 includes the one or more devices that generate IR light. Examples of devices that generate IR light include, for example, IR light bulbs, blue light emitting diodes (LEDs), and other types of IR generating devices. While the IR light source 180 is illustrated as sitting upon the first window 182, the IR light source 180 may sit upon the one or more clamping devices 228, the upper portion 208, both the one or more clamping devices 228 and the upper portion 208, or on legs above the one or more clamping devices 228 and the upper portion 208.

The IR light source 180 transmits IR light through the first window 182, the grid 123, and the second window 184 onto the second (top) surface 186 of the substrate 107. A first thickness (T1) of the first window 182 is greater than a second thickness (T2) of the second window 184. The first window 182 is configured to withstand the first vacuum within the processing chamber 104. The first window 182 may be made of, for example, quartz, sapphire, or another suitable IR light transmissive material. For example only, the first thickness may be approximately 0.8-0.9 inches in the example of the first window 182 being made of quartz or approximately 0.50-0.6 inches in the example of the first window 182 being made of sapphire.

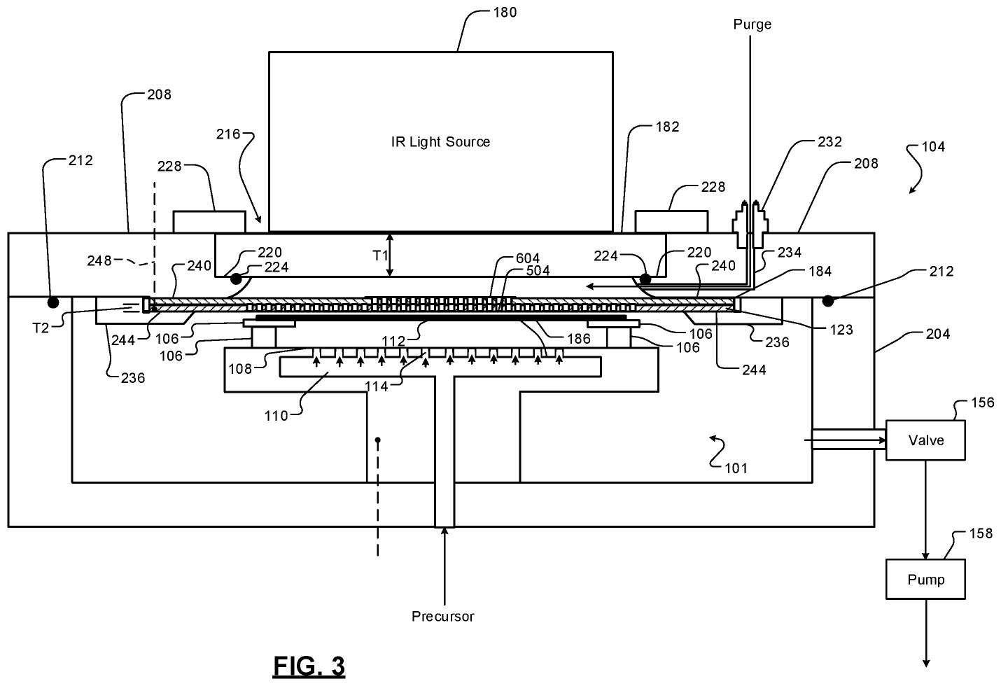

The grid 123 is electrically connected to a potential through the upper portion, as illustrated by 248. The grid 123 is electrically isolated from other electrically conductive surfaces. In the example of FIG. 2, the grid 123 is shown being located between the first window 182 and the second window 184. However, the second window 184 may be located between the grid 123 and the first window 182. For example, FIG. 3 includes a cross-sectional diagram of an example implementation of the processing chamber 104 including the second window 184 located between the grid 123 and the first window 182.

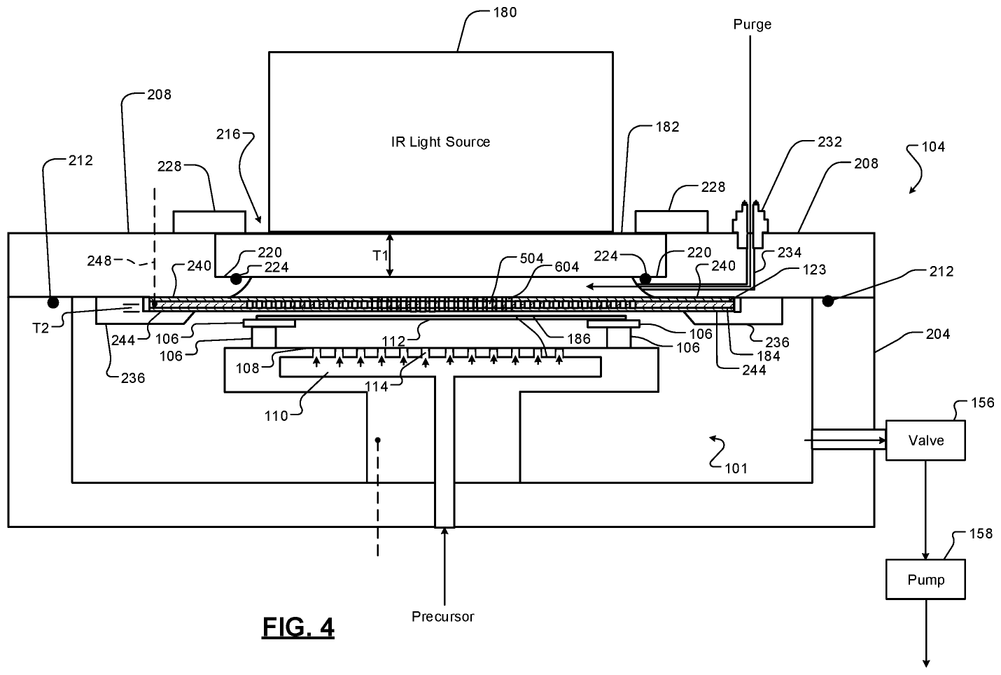

In various implementations, the grid 123 may be embedded within the second window 184. For example, FIG. 4 includes a cross-sectional diagram of an example implementation of the processing chamber 104 including the grid 123 embedded within the second window 184. In various implementations, the second window 184 may be omitted.

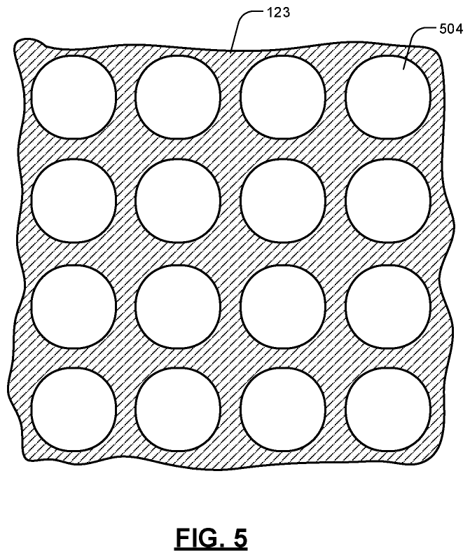

The grid 123 is formed of an electrically conductive material. For example only, the grid 123 may be formed of aluminum or another suitable electrically conductive material. FIG. 5 includes a top view of a portion of an example implementation of the grid 123. The grid 123 may be, for example, circular or rectangular.

The grid 123 includes a plurality of holes 504 through which IR light from the IR light source 180 travels. The grid 123 includes an open area of greater than or equal to approximately 80 percent. For example only, the grid 123 may include an open area of 88 percent, approximately 88 percent, or greater. The grid having an open area of greater than or equal to approximately 80 percent enables sufficient IR light to be transmitted to the substrate 107 to heat the substrate 107 to at least the first temperature during deposition of the film. In various implementations, the holes 504 may be circular, rectangular, triangular, or another suitable shape. The open area of the grid 123 is defined by dimensions (e.g., length and width or radius) of the holes 504 and a pitch of the holes 504 (e.g., triangular, rectangular, staggered, etc.). The open area of the grid 123 refers to the total area of the holes 504 relative to the total area of the grid 123 (including the total area of the holes. For example, the open area of the grid 123 may be determined by dividing the total area of the holes 123 by total area of the grid 123 (including both holes and non-holes). Purge gas also flows through the holes 504. The grid 123 may include 50-300 holes or more in various implementations. In the example of FIG. 5, the grid 123 is shown as having an open area of greater than 80 percent. The grid 123 is shown as having an open area of approximately 88 percent in the example of FIG. 5.

The grid 123 may include a woven mesh of the electrically conductive material in various implementations. Alternatively, the grid 123 may include an etched (e.g., chemically) sheet of the electrically conductive material. Alternatively, the grid 123 may include a plate of the electrically conductive material with the holes 504 formed, for example, via drilling or a water jet.

In various implementations, the grid 123 may be coated. For example, the grid 123 may be coated with one or more materials that are resistant to fluorine etching (e.g., nitrogen triflouride (NF₃) remote plasma or in-situ plasma cleaning). For example, the grid 123 may include a coating of alumina or yytria.

Referring back to FIG. 2, the second window 184 directs purge gas to a center of the substrate 107 and may vertically support the grid 123. The second window 184 may be made of, for example, quartz, sapphire, or another suitable IR light transmissive material. The second thickness (T2) of the second window 184 is less than the first thickness (T1) of the first window 182.

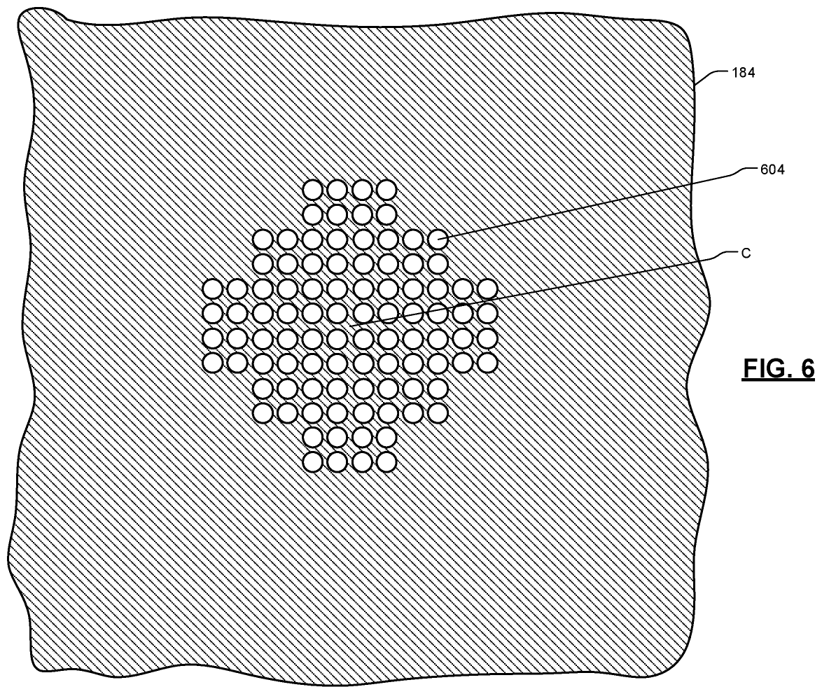

FIG. 6 includes a top view of a portion of an example implementation of the second window 184. The second window 184 includes a plurality of holes 604 through which purge gas flows through the second window 184. The holes 604 may be formed only within a first distance of a center (C) of the second window 184. No holes may be formed within a second distance of edges of the second window 184. The second distance is greater than zero. The second window 184 may be, for example, circular or rectangular. The center C of the second window 184 is located directly above a center of the substrate 107. The holes 604 being formed only near the center of the second window 184 centers purge gas flow to the substrate 107 and enables purge gas to flow radially outwardly from the center of the substrate 107. The purge gas flow minimizes or prevents deposition of the film on the second surface 186 of the substrate 107. Some or all of the holes 504 through the grid 123 are vertically aligned (e.g., coaxial) with ones of the holes 604 through the window 184.

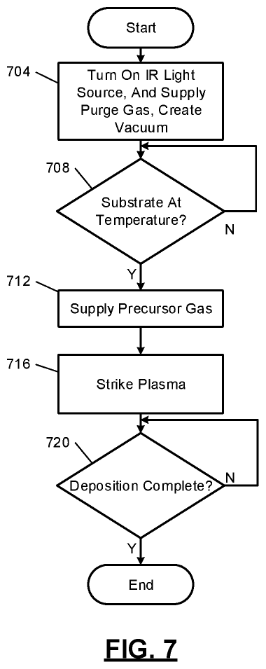

FIG. 7 is a flowchart depicting an example method of depositing the film on the substrate. Control begins with 704 where the system controller 160 turns on the IR light source 180. The system controller 160 may also begin to supply purge gas and create vacuum within the processing chamber 104. The purge gas flows through the grid 123 and the second window 184. The IR light source 180 transmits IR light through the first window 182, the grid 123, and the second window 184 onto the substrate 107 to heat the substrate 107 to at least the first temperature. In various implementations, the system controller 160 may switch the IR light source 180 on and off.

At 708, the system controller 160 may determine whether a temperature of the substrate 107 is equal to or approximately equal to the first temperature. If 708 is true, control may continue with 712. If 708 is false, control may remain at 708 to continue warming the substrate 107. The system controller 160 may determine that the temperature of the substrate 107 is equal to or approximately equal to the first temperature, for example, when a first period has passed since the IR light source 180 was first turned on. Alternatively, one or more temperature sensors may measure the temperature of the substrate 107, and the system controller 160 may compare the measured temperature with the first temperature.

At 712, the system controller 160 may supply the precursor to the first surface 112 of the substrate 107 via the showerhead pedestal 101. At 716, the system controller 160 strikes plasma between the substrate 107 and the top surface 108 of the showerhead pedestal 101 via the grid 123 and the showerhead pedestal 101. For example, the system controller 160 may control the RF generator 122 to apply one of a ground potential and an RF potential to the grid 123 and to apply the other one of the ground potential and the RF potential to the showerhead pedestal 101.

At 720, the system controller 160 may determine whether deposition of the film on the first surface 112 of the substrate 107 is complete. For example, the system controller 160 may determine whether a first period has passed since plasma was struck and deposition of the film began. If 720 is true, control may end. If 720 is false, control may remain at 720 and continue to deposit film from the precursor on the first surface 112 of the substrate 107. Deposition of the film on the substrate 107 while the substrate 107 is approximately at the first temperature minimizes or prevents loss of stress properties of the film during later processes that are performed while the substrate 107 is heated to approximately the first temperature.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A processing chamber, comprising:
a lower portion;
an upper portion that covers the lower portion;
a pedestal that is located within the lower portion, the pedestal to:
vertically support a substrate above a top surface of the pedestal;
distribute a precursor between the top surface of the pedestal and a first surface of the substrate; and
be electrically connected to one of a ground potential and a radio frequency potential;
a grid that is coupled to the upper portion, the grid to be electrically connected to the other one of the ground potential and the radio frequency potential;
a window that covers an opening in the upper portion; and
an infrared light source to transmit infrared light through the window and the grid to a second surface of the substrate,
wherein the second surface of the substrate is opposite the first surface of the substrate.

2. The processing chamber of claim 1 wherein the grid has an open area of approximately 88 percent.

3. The processing chamber of claim 1 wherein the grid has an open area of at least 80 percent.

4. The processing chamber of claim 1 wherein the infrared light source is to heat the substrate to at least 500 degrees Celsius.

5. The processing chamber of claim 1 wherein the grid includes a coating that is resistant to fluorine etching.

6. The processing chamber of claim 1 wherein an exterior of the grid is coated with alumina.

7. The processing chamber of claim 1 wherein an exterior of the grid is coated with yytria.

8. The processing chamber of claim 1 further comprising a radio frequency generator circuit to apply the ground potential and the radio frequency potential to the grid and the pedestal and to strike plasma with the precursor.

9. The processing chamber of claim 1 further comprising a vacuum source to create a vacuum within the processing chamber.

10. The processing chamber of claim 1 further comprising a second window that is coupled to the upper portion,
wherein the infrared light source is to transmit the infrared light through the window, the grid, and the second window to the second surface of the substrate.

11. The processing chamber of claim 10 wherein the second window is located between the grid and the substrate.

12. The processing chamber of claim 10 wherein the second window is located between the window and the grid.

13. The processing chamber of claim 10 wherein the second window includes a plurality of holes.

14. The processing chamber of claim 13 further comprising at least one purge gas conduit to inject a purge gas between the window and the second window,
wherein the purge gas flows through the plurality of holes in the second window toward the second surface of the substrate.

15. The processing chamber of claim 10 wherein a first thickness of the window is greater than a second thickness of the second window.

16. The processing chamber of claim 10 wherein the grid is embedded within the second window.

17. The processing chamber of claim 10 wherein the second window is selected from a group consisting of quartz and sapphire.

18. The processing chamber of claim 1 wherein the window is selected from a group consisting of quartz and sapphire.

19. The processing chamber of claim 1 wherein the infrared light source includes at least one infrared light bulb.

20. The processing chamber of claim 1 wherein the infrared light source includes a plurality of blue light emitting diodes to generate infrared light.

21. A processing chamber, comprising:
a pedestal that is located within the processing chamber, the pedestal to:
vertically support a substrate; and
be electrically connected to one of a ground potential and a radio frequency potential;
a grid to be electrically connected to the other one of the ground potential and the radio frequency potential,
wherein the substrate is between the grid and the pedestal;
a window; and
an infrared light source to transmit infrared light through the window and the grid to a surface of the substrate.

22. The processing chamber of claim 21 wherein the grid has an open area of approximately 88 percent.

23. The processing chamber of claim 21 wherein the grid has an open area of at least 80 percent.

24. The processing chamber of claim 21 wherein the infrared light source is to heat the substrate to at least 500 degrees Celsius.

25. The processing chamber of claim 21 wherein the grid includes a coating that is resistant to fluorine etching.

26. The processing chamber of claim 21 wherein an exterior of the grid is coated with alumina.

27. The processing chamber of claim 21 wherein an exterior of the grid is coated with yytria.

28. The processing chamber of claim 21 further comprising a radio frequency generator circuit to apply the ground potential and the radio frequency potential to the grid and the pedestal and to strike plasma with a precursor.

29. The processing chamber of claim 21 further comprising a vacuum source to create a vacuum within the processing chamber.

30. The processing chamber of claim 21 further comprising a second window,
wherein the infrared light source is to transmit the infrared light through the window, the grid, and the second window to the surface of the substrate.

31. The processing chamber of claim 30 wherein the second window is located between the grid and the substrate.

32. The processing chamber of claim 30 wherein the second window is located between the window and the grid.

33. The processing chamber of claim 30 wherein the second window includes a plurality of holes.

34. The processing chamber of claim 33 further comprising at least one purge gas conduit to inject a purge gas between the window and the second window,
wherein the purge gas flows through the plurality of holes in the second window toward the surface of the substrate.

35. The processing chamber of claim 30 wherein a first thickness of the window is greater than a second thickness of the second window.

36. The processing chamber of claim 30 wherein the grid is embedded within the second window.

37. The processing chamber of claim 30 wherein the second window is selected from a group consisting of quartz and sapphire.

38. The processing chamber of claim 21 wherein the window is selected from a group consisting of quartz and sapphire.

39. The processing chamber of claim 21 wherein the infrared light source includes at least one infrared light bulb.

40. The processing chamber of claim 21 wherein the infrared light source includes a plurality of blue light emitting diodes to generate infrared light.
